(19) United States
(12) Patent Application Publication
(10) Pub. No.: US 2026/0060083 A1
(43) Pub. Date: Feb. 26, 2026

(54) SEMICONDUCTOR PACKAGE AND SEMICONDUCTOR MODULE INCLUDING THE SAME

(71) Applicant: Samsung Electronics Co., Ltd., Suwon-si (KR)

(72) Inventor: INHEE YOO, Suwon-si (KR)

(21) Appl. No.: 19/073,265

(22) Filed: Mar. 7, 2025

(30) Foreign Application Priority Data
Aug. 20, 2024 (KR) 10-2024-0111421

(51) Int. Cl. H01L 23/373; H01L 23/498

(52) U.S. Cl. CPC H01L 23/3736; H01L 23/49816; H01L 23/49866

(57) ABSTRACT

The present disclosure relates to a semiconductor package. An embodiment of the present disclosure provides a semiconductor package including: a package substrate; a semiconductor chip positioned on a first surface of the package substrate; a pad positioned on a second surface of the package substrate; a solder resist layer including an opening positioned on the second surface of the package substrate and the pad, the solder resist layer vertically overlapping at least a portion of the pad, the solder resist layer including a dummy opening spaced apart from the opening; and a filling layer positioned within the dummy opening, wherein the dummy opening is positioned farther than the opening from a center of the package substrate in a plan view.

### CROSS-REFERENCE TO RELATED APPLICATION

This application claims priority to and the benefit of Korean Patent Application No. 10-2024-0111421, filed in the Korean Intellectual Property Office on Aug. 20, 2024, the entire contents of which are incorporated herein by reference.

### BACKGROUND OF THE DISCLOSURE

### 1. Field of the Disclosure

The present disclosure relates to a semiconductor package and a semiconductor module including the same.

### 2. Description of the Related Art

Semiconductor devices are becoming increasingly smaller, thinner, and lighter due to recent miniaturization of electronic devices. In addition, semiconductor modules in which a large number of semiconductor devices/chips are mounted on a substrate are becoming increasingly highly integrated.

A semiconductor package including a semiconductor chip may be mounted on a module using a soldering method. In the soldering process, a certain amount of solder material (usually solder paste) is positioned on multiple connection terminals and a certain temperature is applied, so the solder material is shaped into a spherical shape by the action of surface tension. Such a solder material of this spherical shape may be called a solder ball.

Board level reliability (BLR) is a concept for evaluating reliability and durability of semiconductor packages and modules, and BLR tests may include temperature cycling, humidity testing, mechanical stress testing, electrical stress testing, etc.

A major factor that has a significant impact on semiconductor packages and modules in temperature cycling tests is a difference in coefficient of temperature expansion (CTE) between the semiconductor module and the package. This difference in the CTE may cause a horizontal force to be applied at a joint portion between the module and the package, which may significantly affect the reliability of the semiconductor package and the module. Accordingly, in order to increase reliability of semiconductor packages and modules, it is necessary to reduce the stress that may occur in solder balls.

### SUMMARY

Embodiments improve operational reliability of a semiconductor package according to temperature changes.

Furthermore, the embodiments reduce a solder ball stress due to a difference in coefficient of temperature expansion (CTE) between a semiconductor package and a module substrate.

An embodiment of the present disclosure provides a semiconductor package including: a package substrate; a semiconductor chip positioned on a first surface of the package substrate; a pad positioned on a second surface of the package substrate; a solder resist layer including an opening positioned on the second surface of the package substrate and the pad, the solder resist layer vertically overlapping at least a portion of the pad, the solder resist layer including a dummy opening spaced apart from the opening; and a filling layer positioned within the dummy opening, wherein the dummy opening is positioned farther than the opening from a center of the package substrate in a plan view.

Furthermore, an embodiment of the present disclosure provides a semiconductor package including: a package substrate; a semiconductor chip positioned on a first surface of the package substrate; a plurality of pads positioned on a second surface of the package substrate; a solder resist layer including a plurality of openings positioned on the package substrate and the pads, the plurality of openings exposing the plurality of pads respectively, the solder resist layer including a dummy opening positioned apart from the openings; and a filling layer positioned within the dummy opening.

An embodiment of the present disclosure provides a semiconductor module including: a package substrate; a semiconductor chip positioned on a first surface of the package substrate; a pad positioned on a second surface of the package substrate; a solder resist layer including an opening positioned on the package substrate and the pad, the opening vertically overlapping at least a portion of the pad, the solder resist layer including a dummy opening spaced apart from the opening; a filling layer positioned within the dummy opening; and a solder ball positioned within the opening.

According to the embodiments, operational reliability of a semiconductor package may be improved under conditions of temperature changes.

Furthermore, according to the embodiments, stress occurring in a solder ball may be reduced.

### BRIEF DESCRIPTION OF THE DRAWINGS

FIG. 1 illustrates a top/plan view of a semiconductor module according to an embodiment.

FIG. 2 illustrates a top/plan view showing a portion of a semiconductor module according to an embodiment.

FIG. 3 to FIG. 7 each illustrate a top/plan view showing some components of a semiconductor package according to an embodiment.

FIG. 8 illustrates a cross-sectional view taken along a line A-A′ of FIG. 2.

FIG. 9 to FIG. 11 each illustrate an enlarged view of a region E of FIG. 8.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are not clearly relevant to the main aspects of the disclosure may be omitted, and like numerals refer to like or similar components throughout the specification.

Further, since sizes and thicknesses of constituent members shown in the accompanying drawings are arbitrarily given for better understanding and ease of description, the inventive concept is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

As used herein, components described as being “electrically connected” are configured such that an electrical signal can be transferred from one component to the other (although such electrical signal may be attenuated in strength as it is transferred and may be selectively transferred).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

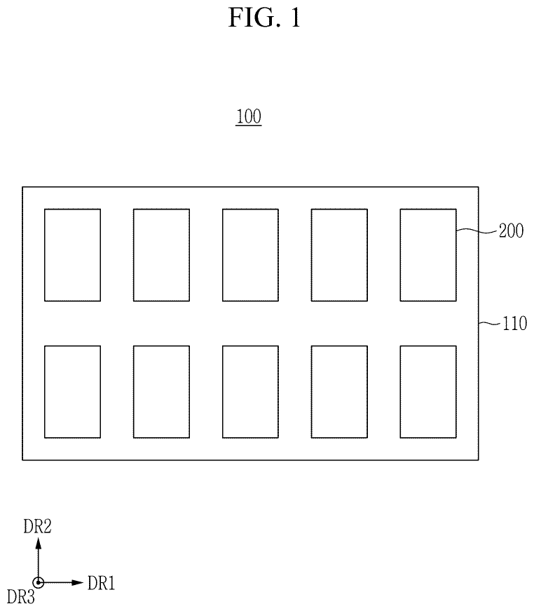

FIG. 1 illustrates a top/plan view of a semiconductor module according to an embodiment.

Referring to FIG. 1, a semiconductor module 100 according to an embodiment may include a module substrate 110 and a semiconductor package 200 positioned on the module substrate 110.

The module substrate 110 may include a first surface and a second surface opposite to the first surface. The first and second surfaces may be opposite each other in a third direction DR3. The semiconductor package 200 may be positioned on the first surface of the module substrate 110. For example, the module substrate 110 may include or may be a printed circuit board (PCB).

One or more semiconductor packages 200 may be positioned on the module substrate 110. The semiconductor packages 200 positioned on the module substrate 110 may be arranged with uniform or uneven (variable) distances from each other, and may be positioned in various ways as needed.

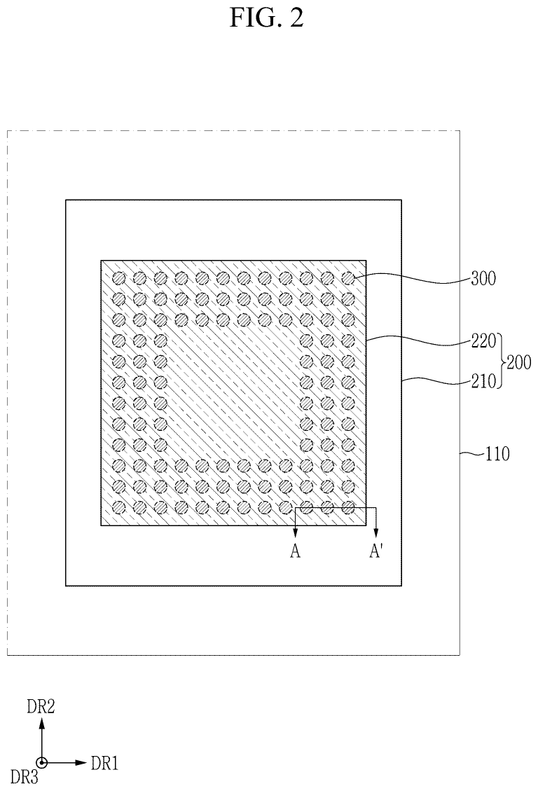

FIG. 2 illustrates a top/plan view showing a portion of a semiconductor module according to an embodiment.

Referring to FIG. 2, the semiconductor packages 200 may be positioned on the module substrate 110. The semiconductor package 200 may include a package substrate 210 and a semiconductor chip 220.

The package substrate 210 may include a first surface and a second surface opposite to the first surface. The first and second surfaces may be opposite each other in a third direction DR3. The semiconductor chip 220 may be positioned on the first surface of the package substrate 210. For example, the package substrate 210 may include or may be a printed circuit board (PCB). For example, the first surface of the package substrate 210 on which the semiconductor chip 220 is positioned may be an upper surface.

The semiconductor package 200 may be electrically interconnected with the module substrate 110 through one or more solder balls 300. The solder balls 300 may be positioned between the module substrate 110 and the semiconductor package 200. The solder balls 300 may be positioned on the second surface of the package substrate 210. For example, the second surface of the package substrate 210 on which the solder balls 300 are positioned may be a lower surface of the package substrate 210. Furthermore, the solder balls 300 may be positioned on a first surface of the module substrate 110. For example, a first surface of the module substrate 110 on which the solder balls 300 are positioned may be an upper surface of the module substrate 110.

A plurality of solder balls 300 may be arranged according to a predetermined rule, but the inventive concept is not limited thereto, and may be arranged irregularly or according to various rules that are changed/adjusted as needed.

A coefficient of thermal expansion (CTE) of the semiconductor package 200 may be calculated by considering coefficients of thermal expansion (CTE) of the package substrate 210, the semiconductor chip 220, and other components included in the semiconductor package 200.

For example, the CTE of the semiconductor package 200 may be calculated by considering Young's modulus and CTEs of the components included in the semiconductor package 200. For example, as the Young's modulus of one component of the semiconductor package 200 and the CTE of another component of the semiconductor package 200 increase, the CTE of the semiconductor package 200 may increase in certain combinations. While a material having a higher Young's modulus than another material may have a lower CTE than the other material, a combination of a first component formed of a first material having a higher Young's modulus than a second material and a second component formed of the second material having a higher CTE than the first material may increase expansion rate of a semiconductor package according to temperature changes more than a third component formed of only the second material. For example, as the Young's modulus of one component of the semiconductor package 200 increases, a thermal expansion strength of the semiconductor package 200 may be strengthened. In the present disclosure, CTE of a device or a component may represent an expansion rate of the corresponding device or component by changes of temperature or CTE of a material forming the corresponding component depending on the context. For example, CTE of a device or a component may be determined either by way of CTE of a constituent material of the device or the component or by an expansion rate of the device as a whole or the component as a whole according to temperature changes if the context does not indicate otherwise. For example, the CTE of the semiconductor package 200 may be an expansion rate of the semiconductor package 200 as a whole when the temperature of the semiconductor package 200 changes.

The semiconductor package 200 may be electrically connected to the module substrate 110 through the solder balls 300. The CTE of semiconductor package 200 may be different from the CTE of the module substrate 110. For example, the CTE of the semiconductor package 200 may be smaller than the CTE of the module substrate 110, but the inventive concept is not limited thereto.

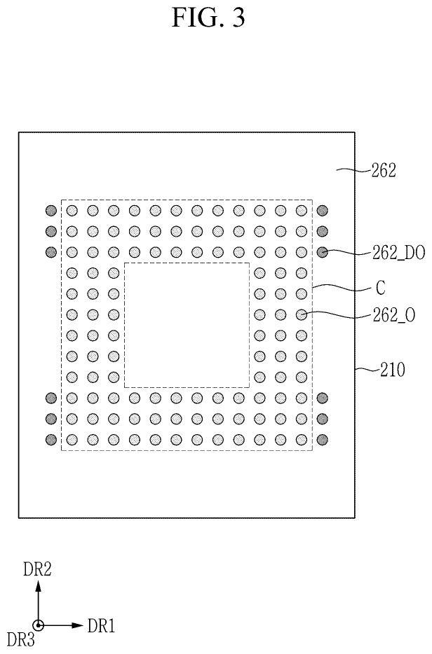

FIG. 3 to FIG. 7 each illustrate a top/plan view showing some components of a semiconductor package according to an embodiment.

Referring to FIGS. 3 to 7, a second package solder resist layer 262 may be positioned on the second surface of the package substrate 210 according to an embodiment. For example, the second surface of the package substrate 210 may be/indicate a lower surface of the package substrate 210.

The second package solder resist layer 262 may include a second package solder resist layer opening 262_O and a dummy opening 262_DO. Each of the second package solder resist layer opening 262_O and the dummy opening 262_DO may be/indicate an area where the second package solder resist layer 262 is removed. For example, the opening 262_O and the dummy opening 262_DO may be formed in the second package solder resist layer 262 by removing portions of the second package solder resist layer 262. The second package solder resist layer opening 262_O may serve to provide a space for the second package pad 264 and the solder ball 300 to come into contact each other. For example, the solder ball 300 may be positioned within the opening. For example, at least a portion of the solder ball 300 may overlap at least a portion of the second package solder resist layer opening 262_O in a horizontal direction. Additional details with respect to second package pad 264 and the solder ball 300 will be described later.

A filling layer 266, which will be described later, may be positioned within the dummy opening 262_DO. The second package solder resist layer opening 262_O and the dummy opening 262_DO may be arranged spaced apart from each other.

The second package solder resist layer 262 may include one or more second package solder resist layer openings 262_O. For example, the one or more second package solder resist layer openings 262_O may be arranged in a lattice/grid shape in a plan view. Furthermore, the one or more second package solder resist layer openings 262_O arranged in a plan view may form an opening area C. An opening area C defined by the one or more second package solder resist layer openings 262_O may be a concept including the second package solder resist layer openings 262_O and their surrounding area. For example, the second package solder resist layer openings 262_O may be regularly arranged in the opening area C. For example, the opening area C may include the regularly arranged second package solder resist layer openings 262_O and spaces between the regularly arranged second package solder resist layer openings 262_O. For example, distances between neighboring second package solder resist layer openings 262_O may be the same in the opening area C.

Referring to FIG. 3 to 7, for better understanding and ease of description, a plurality of second package solder resist layer openings 262_Os may be arranged in a quadrangular ring shape, and the opening area C may also have a quadrangular ring shape, but the inventive concept is not limited thereto. For example, the second package solder resist layer openings 262_Os may be arranged according to a predetermined rule, but the inventive concept is not limited thereto, and may be arranged irregularly or according to various rules that are changed/modified as needed. Furthermore, the number and shape of the opening area C may be varied as needed.

The second package solder resist layer 262 may include one or more dummy openings 262_DO. Each of the dummy openings 262_DO may be positioned between a second package solder resist layer opening 262_O (or the opening area C) and one edge of the package substrate 210. The dummy opening 262_DO may be positioned further outward (e.g., closer to an edge of the package substrate 210) than the second package solder resist layer opening 262_O in the package substrate 210. For example, the dummy opening 262_DO may be positioned closer to an edge of the package substrate 210 than the adjacent second package solder resist layer opening 262_O. Furthermore, the dummy opening 262_DO may be positioned further from a center of the package substrate 210 than the adjacent second package solder resist layer opening 262_O. For example, the dummy opening 262_DO may be positioned outside of the opening area C in which one or more second package solder resist layer openings 262_O are positioned, and may be positioned at a first side portion. Furthermore, the dummy opening 262_DO may be positioned between the second package solder resist layer opening 262_O and a first vertex of the package substrate 210. For example, the dummy opening 262_DO may be positioned at an outside of a corner of the opening area C in which one or more second package solder resist layer openings 262_O are positioned. For example, the dummy opening 262_DO may be positioned at a corner of the package substrate 210.

The second package solder resist layer opening 262_O and the dummy opening 262_DO may indicate an opening positioned to extend through the second package solder resist layer 262. For example, the second package solder resist layer opening 262_O may penetrate through the second package solder resist layer 262 in a vertical direction (e.g., in the third direction DR3) from a top surface to a bottom surface of the second package solder resist layer 262.

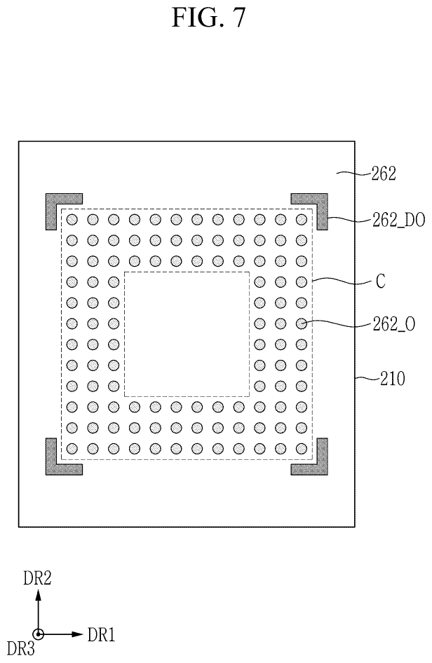

Referring to FIGS. 3 to 7, for better understanding and ease of description, the second package solder resist layer openings 262_O are illustrated as circles, but the inventive concept is not limited thereto. Furthermore, for better understanding and ease of description, referring to FIGS. 3 to 6, the dummy openings 262_DO are illustrated as circles, and referring to FIG. 7, the dummy openings 262_DO are illustrated as L-shapes, but the inventive concept is not limited thereto. The dummy openings 262_DO may have any of the following shapes, e.g., a circle (a circular shape), an oval (e.g., an elliptical shape), a polygon, an L-shape, a C-shape, and a ring-shape (e.g., an annular shape), but the inventive concept is not limited thereto, and may be variously changed/modified as needed.

Furthermore, the dummy openings 262_DO may be arranged according to a certain rule such as left-right symmetry, up-down symmetry, origin symmetry (e.g., with respect to a central point of the package substrate 210), clockwise rotational symmetry, counterclockwise rotational symmetry, etc., but the inventive concept is not limited thereto, and the dummy openings 262_DO may be arranged asymmetrically or irregularly. Furthermore, referring to FIGS. 3 to 7, the same number of dummy openings 262_DO may be positioned on each side or vertex of the opening area C, but the inventive concept is not limited thereto, and a different number of dummy openings 262_DO may be positioned, and may be varied as needed.

Referring to FIG. 3, in an embodiment, the dummy openings 262_DO may be arranged on a side surface of the opening area C. For example, the dummy openings 262_DO may be arranged adjacent to vertices of the opening area C, and the openings 262_DO having the same number and the same arrangement may be arranged at each vertex of the opening area C. For example, the dummy openings 262_DO may be arranged adjacent to each vertex of the opening area C, and the dummy openings 262_DO may be arranged symmetrically left and right (e.g., bilateral symmetry) with respect to the opening area C.

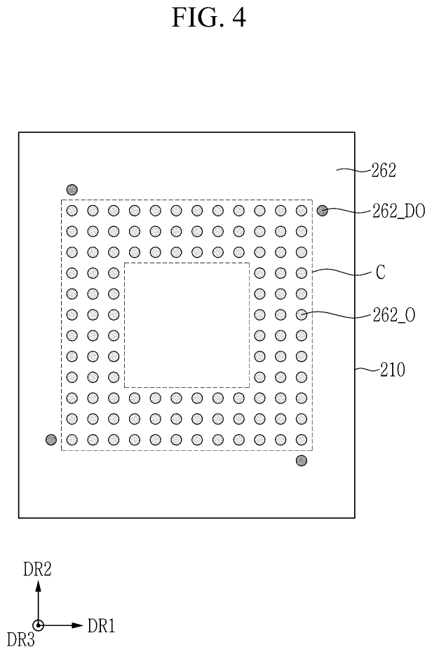

Referring to FIG. 4, for example, the dummy openings 262_DO according to an embodiment may be arranged one by one on a side surface of the opening area C. For example, one dummy opening 262_DO may be disposed on each outer side of the opening area C as shown in FIG. 4. For example, the dummy openings 262_DO may be arranged one by one adjacent to each vertex of the opening area C, and may be arranged rotationally symmetrically at a 90 degree angle around a center of the opening area C. For example, one dummy opening 262_DO may be disposed on each outer side of the opening area C to be closer to one vertex than the other such that the dummy openings 262_DO are arranged to be 90 degree rotational symmetry arrangement as shown in FIG. 4.

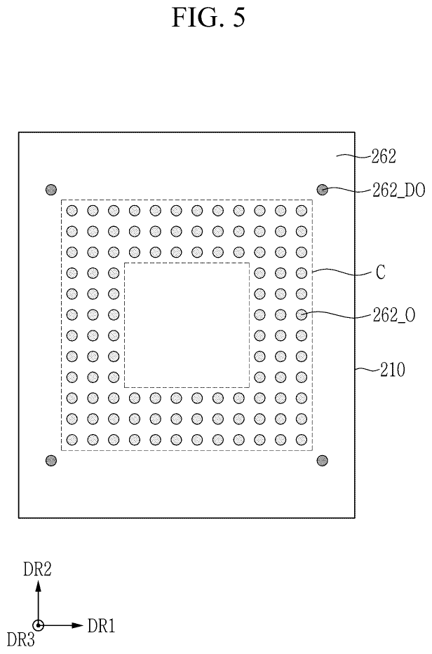

Referring to FIG. 5, for example, the dummy openings 262_DO according to an embodiment may be arranged on an outer part of the package substrate 210 outside the opening area C, and may be arranged one by one at each outer corner of the package substrate 210. For example, the dummy openings 262_DO may be arranged one by one adjacent to each vertex of the opening area C, may be arranged between a vertex of the opening area C and a vertex of the package substrate 210, and may be arranged so as to be symmetrical above and below and left and right of the opening area C.

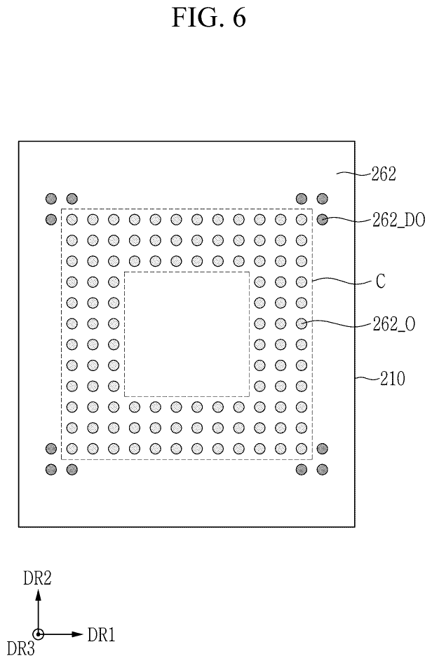

Referring to FIG. 6, in an embodiment, the dummy openings 262_DO may be arranged outside or at an outer corner of the opening area C. For example, the dummy openings 262_DO may be arranged adjacent to each vertex of the opening area C, and the dummy openings 262_DO may be arranged symmetrically above and below and left and right with respect to the opening area C. For example, the dummy openings 262_DO arranged adjacent to each vertex of the opening area C may be arranged in an L shape. For example, a plurality of dummy openings 262_DO may be disposed adjacent to each vertex of the opening area C such that lines connecting center points of closest dummy openings 262_DO to each other form an L shape as shown in FIG. 6.

Referring to FIG. 7, for example, the dummy openings 262_DO according to an embodiment may be arranged on an outer part of the package substrate 210 outside the opening area C, may be arranged outside the corners of the opening area C, and the dummy openings 262_DO may have an L-shaped shape. For example, the dummy openings 262_DO may be arranged at corners of the package substrate 210.

A shape and position of the second solder resist layer opening 262_O and the dummy opening 262_DO of FIGS. 3 to 7 are not limited thereto, and may be changed/adjusted in various ways as needed. In a process of manufacturing the semiconductor package 200, the second package solder resist layer openings 262_O may be formed together with the dummy openings 262_DO, but the inventive concept is not limited thereto.

As the dummy openings 262_DO are positioned in the package substrate 210 and a filling layer 266 is positioned within the dummy openings 262_DO, a stress applied to the solder balls 300 that may occur due to a difference in CTE between the semiconductor package 200 and the module substrate 110 may be reduced. For example, an expansion force of the semiconductor package 200 may be increased by the dummy openings 262_DO and the filling layer 266 positioned in the second package solder resist layer 262 on the package substrate 210, thereby reducing a CTE difference with the module substrate 110, and a stress applied to the solder balls 300 may be reduced. For example, the CTE of the semiconductor package 200 may be smaller than the CTE of the module substrate 110, and the CTE of the filling layer 266 may be greater than the CTE of the second package solder resist layer 262. Therefore, by forming the filling layer 266 in the dummy openings 262_DO of the second package solder resist layer 262, the filling layer 266 may increase the CTE of the semiconductor package 200 such that a difference between the CTE of the module substrate 110 and the CTE of the semiconductor package 200 is reduced, thereby reducing the stress applied to the solder balls 300.

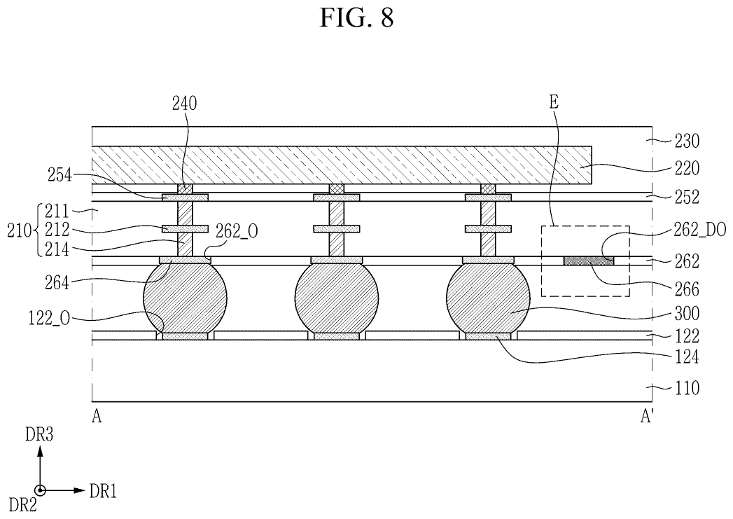

FIG. 8 illustrates a cross-sectional view taken along a line A-A′ of FIG. 2.

Referring to FIG. 8, one or more solder balls 300 may be positioned on the module substrate 110, and the semiconductor package 200 may be electrically connected to the module substrate 110 via the solder balls 300. The package substrate 210 may be positioned on the solder balls 300 and the module substrate 110. Furthermore, the semiconductor chip 220 may be positioned on the package substrate 210, and the semiconductor chip 220 may be covered by an encapsulant 230 on the package substrate 210.

The semiconductor package 200 may include a connecting member 240 described below, a first package solder resist layer 252, a first package pad 254, a second package solder resist layer 262, a second package solder resist layer opening 262_O, a second package pad 264, a dummy opening 262_DO, and a filling layer 266.

The module substrate 110 may perform a function of integrating multiple semiconductor chips 220 and/or other components. The module substrate 110 may include, but is not limited to, a thermosetting resin such as an epoxy resin, a thermoplastic resin such as polyimide, or a photosensitivity resin, and the material of the module substrate 110 may include or be changed to a variety of insulating resins.

The module solder resist layer 122 may be positioned on the module substrate 110. Furthermore, a module pad 124 may be positioned on the module substrate 110. The module pad 124 may include a conductive material. For example, the module pad 124 may include, but is not limited to, copper (Cu), aluminum (Al), silver (Ag), tin (Sn), gold (Au), nickel (Ni), lead (Pb), titanium (Ti), or an alloy thereof.

The module solder resist layer 122 may include a module solder resist layer opening 122_O that at least partially exposes the module substrate 110 and/or the module pad 124. For example, the module solder resist layer opening 122_O may overlap at least a portion of the module pad 124, e.g., in a vertical direction (the third direction DR3).

The module solder resist layer 122 may be positioned to cover at least a portion of the module pad 124, or may be positioned apart from the module pad 124 (e.g., in a horizontal direction—the first/second directions DR1/DR2) by a certain distance.

A thickness of the module solder resist layer 122 may be defined/formed to be the same as or different from a thickness of the second package solder resist layer 262 described later.

The solder balls 300 may be positioned on the module pad 124, and the module pad 124 may be electrically and physically connected to the solder balls 300.

The solder balls 300 may electrically connect the package substrate 210 to an external component. The external component may include, e.g., a main board or motherboard of an electronic device. Each of the solder balls 300 may have a ball shape.

The solder balls 300 may include, e.g., an alloy such as tin (Sn), lead (Pb), silver (Ag), or copper (Cu), but the inventive concept is not limited thereto.

The solder balls 300 may be electrically connected to second package pads 264 positioned on a second surface of the package substrate 210.

A lower surface of the module solder resist layer 122 may be positioned at the same or substantially the same level as a lower surface of the module pad 124, but the inventive concept is not limited thereto.

The package substrate 210 may include an insulating layer 211, a wiring layer 212, and a via 214. The insulating layer 211 may include, but is not limited to, a thermosetting resin such as an epoxy resin, a thermoplastic resin such as polyimide, or a photosensitivity resin, and the material of the insulating layer 211 may include or be changed to a variety of insulating resins.

The wiring layer 212 may include a conductive material. For example, the wiring layer 212 may include, but is not limited to, copper (Cu), aluminum (Al), silver (Ag), tin (Sn), gold (Au), nickel (Ni), lead (Pb), titanium (Ti), or an alloy thereof.

The wiring layer 212 may perform various functions depending on a design of the layer. For example, the wiring layer 212 may include a ground (GND) pattern, a power (PWR) pattern, and/or a signal (S) pattern. Herein, the signal (S) pattern may include various signal patterns transferring various signals, such as a data signal, excluding the ground (GND) pattern and the power (PWR) pattern.

One or more wiring layers 212 may be arranged in the package substrate 210, and for example, a plurality of wiring layers 212 may be positioned in the package substrate 210 at different levels in the third direction DR3.

The via 214 may electrically connect between the wiring layers 212 positioned at different levels. The via 214 may include a conductive material. For example, the via 214 may be formed in a via hole completely filled with a conductive material, but the inventive concept is not limited thereto. As another example, the via 214 may be formed with a conductive material formed along a wall surface of a via hole.

For better understanding and ease of description, in FIG. 8, a width of the via 214 (width along the first direction DR1 and/or the second direction DR2) is depicted as being constant, but the width of the via 214 may become narrower or wider moving in the third direction DR3. For example, in a via hole etching process, the width may become narrower in a direction receding from a level/layer where etching begins and approaching a level/layer where etching ends.

At least one via 214 may have a form extending through the insulating layer 211 positioned between adjacent wiring layers 212 in the third direction DR3. The insulating layer 211 may surround at least one wiring layer 212 and at least one via 214. The insulating layer 211 may surround an upper surface, a lower surface, and a side surface of at least one wiring layer 212. The insulating layer 211 may surround a side surface of at least one via 214.

The second package solder resist layer 262 may be positioned on the second surface of the package substrate 210. Furthermore, the second package pad 264 may be positioned on a second surface of the package substrate 210. The second package solder resist layer 262 may include a second package solder resist layer opening 262_O that exposes at least a portion of the second surface of the package substrate 210 and/or the second package pad 264. For example, the second package solder resist layer opening 262_O may at least partially overlap the second package pad 264, e.g., in the third direction DR3.

For example, the second surface of the package substrate 210 on which the second package solder resist layer 262 and the second package pad 264 are positioned may be a lower surface of the package substrate 210.

The second package solder resist layer 262 may be positioned to cover at least a portion of the second package pad 264, or may be positioned apart from the second package pad 264. For example, a solder mask defined (SMD) method and/or a non solder mask defined (NSMD) method may be applied to the semiconductor module 100 according to an embodiment. For example, the second package solder resist layer 262 may cover a portion of the second package pad 264 when the SMD method is applied to the semiconductor module 110, and the second package solder resist layer 262 may not vertically overlap the second package pad 264 when the NSMD method is applied to the semiconductor module 110.

The second package pad 264 may include a conductive material, like the module pad 124. The second package pad 264 may be positioned on the solder ball 300. The second package pad 264 may be electrically and physically connected to solder ball 300. For example, the second package pad 264 may be positioned so as to face each other with the module pad 124 and the solder ball 300 positioned on the module substrate 110 provided therebetween.

An upper surface of the second package solder resist layer 262 may be positioned at the same or substantially the same level as the upper surface of the second package pad 264, but the inventive concept is not limited thereto.

Furthermore, the dummy opening 262_DO may be positioned in the second package solder resist layer 262. The dummy opening 262_DO may be positioned apart from the second package solder resist layer opening 262_O. Furthermore, the dummy opening 262_DO may be positioned apart from the second package pad 264. For example, the dummy opening 262_DO may be positioned such that a side surface does not come into contact with the second package solder resist layer opening 262_O and such that it does not partially overlap the second package pad 264. The dummy opening 262_DO may be positioned further outward (e.g., closer to an edge of the package substrate 210) than the second package solder resist layer opening 262_O in the package substrate 210. For example, the dummy opening 262_DO may be positioned closer to an edge of the package substrate 210 than the adjacent second package solder resist layer opening 262_O. Furthermore, the dummy opening 262_DO may be positioned farther from a center of the package substrate 210 than the adjacent second package solder resist layer opening 262_O.

The filling layer 266 may be positioned within the dummy opening 262_DO. The filling layer 266 may have a higher Young's modulus than that of the second package solder resist layer 262. In this case, the expansion rate of the semiconductor package 200 according to temperature changes may be higher than a semiconductor package which does not include the filling layer 266 in the second package solder resist layer 262.

The filling layer 266 may include a conductive material. For example, the filling layer 266 may include at least one of tin (Sn), lead (Pb), silver (Ag), copper (Cu), bismuth (Bi), indium (In), antimony (Sb), zinc (Zn), gold (Au), or nickel (Ni). Furthermore, by way of example, the filling layer 266 may include copper (Cu). However, the material of the filling layer 266 is not limited thereto. For example, the filler layer 266 may include an insulating material. For example, various materials may be used as a constituent material of the filling layer 266 to control a CTE of the semiconductor package 200, e.g., to reduce difference between the CTE of the module substrate 110 and the CTE of the semiconductor package 200.

The filling layer 266 may be positioned apart from the wiring layer 212, the via 214, the second package pad 264, and the solder ball 300. For example, the filling layer 266 may be positioned to not make any contact with the wiring layer 212, the via 214, the second package pad 264, and the solder ball 300. The dummy opening 262_DO and the filling layer 266 may be positioned so as to prevent a short circuit from occurring in the semiconductor package 200.

A thickness of the second package solder resist layer 262 may be any one of 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, and 30 μm, but the inventive concept is not limited thereto. For example, the thickness of the second package solder resist layer 262 may be any thickness from 1 μm to 30 μm, and in some embodiments, may be greater than or equal to about 10 μm and smaller than or equal to about 20 μm.

The second package solder resist layer opening 262_O and the dummy opening 262_DO may be an opening positioned to extend through the second package solder resist layer 262. For example, the second package solder resist layer opening 262_O may penetrate through the second package solder resist layer 262 in a vertical direction (e.g., in the third direction DR3) from a top surface of the second package solder resist layer 262 to a bottom surface of the second package solder resist layer 262. Accordingly, a depth of the second package solder resist layer opening 262_O and the dummy opening 262_DO may correspond to a thickness of the second package solder resist layer 262. For example, depths of the second package solder resist layer opening 262_O and the dummy opening 262_DO may be equal to or substantially equal to the thickness of the second package solder resist layer 262. The depths of the second package solder resist layer opening 262_O and the dummy opening 262_DO may be any one of 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, and 30 μm, but the inventive concept is not limited thereto. For example, the depths of the second package solder resist layer opening 262_O and the dummy opening 262_DO may be any depth from 1 μm to 30 μm, but is not limited to, and in some embodiments, may be about 10 μm or more and about 20 μm or less.

The first package solder resist layer 252 may be positioned on the first surface of the package substrate 210. Furthermore, the first package pad 254 may be positioned on the first surface of the package substrate 210.

For example, the first surface of the package substrate 210 on which the first package solder resist layer 252 and the first package pad 254 are positioned may be an upper surface of the package substrate 210.

The first package solder resist layer 252 may be positioned to cover at least a portion of the first package pad 254, or may be positioned apart from the first package pad 254. For example, a solder mask defined (SMD) method and/or a non solder mask defined (NSMD) method may be applied to the semiconductor module 100 according to an embodiment.

A lower surface of the first package solder resist layer 252 may be positioned at the same or substantially the same level as a lower surface of the first package pad 254, but the inventive concept is not limited thereto.

A thickness of the first package solder resist layer 252 may be defined to be the same as or different from a thickness of the second package solder resist layer 262.

The first package pad 254 may include a conductive material, like the module pad 124. The first package pad 254 may be electrically connected to the semiconductor chip 220 via the connecting member 240.

The connecting member 240 may be/indicate, e.g., a bump (e.g., a solder bump or a solder column), but the inventive concept is not limited thereto. The connecting member 240 may include a conductive material, e.g., a metal such as copper (Cu), aluminum (Al), gold (Au), silver (Ag), or nickel (Ni). For example, the connecting member 240 may be formed by a plating or sputtering process.

The connecting member 240 may have a column shape, for example. A plan view shape of the connecting member 240 may be, e.g., a circle, an ellipse, a quadrangle, or a hexagon, but the inventive concept is not limited thereto, and it may be varied in various ways.

The connecting member 240 may be positioned to contact an upper surface of the first package pad 254.

The semiconductor chip 220 may be encapsulated on the first surface of the package substrate 210 by the encapsulant 230. The encapsulant 230 may cover the upper and side surfaces of the semiconductor chip 220. The encapsulant 230 may surround and contact the side surface of the connecting member 240 between the lower surface of the semiconductor chip 220 and the first surface of the package substrate 210.

The encapsulant 230 may include, e.g., an epoxy molding compound (EMC), but the inventive concept is not limited thereto.

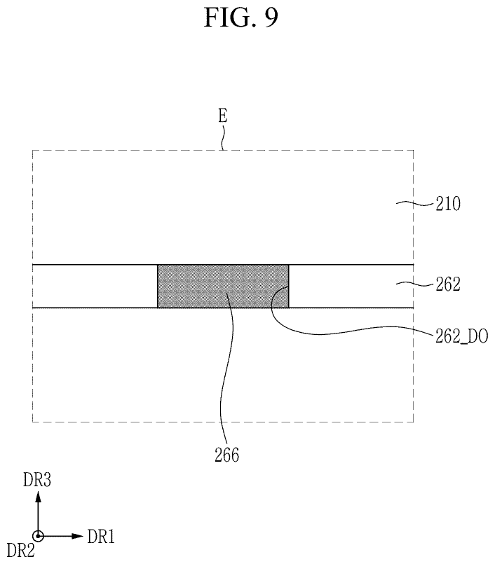

FIG. 9 to FIG. 11 each illustrate an enlarged view of a region E of FIG. 8.

Referring to FIG. 9 to FIG. 11, the second package solder resist layer 262 may be positioned on the second surface of the package substrate 210. Furthermore, the dummy opening 262_DO may be positioned in the second package solder resist layer 262, and the filling layer 266 may be positioned within the dummy opening 262_DO.

Referring to FIG. 9, the filling layer 266 according to an embodiment may be positioned to completely fill the dummy opening 262_DO.

For example, an upper surface of the filling layer 266 may be positioned to contact the lower surface of the package substrate 210. The upper surface of the filling layer 266 may be positioned at the same or substantially the same level as the upper surface of the second package solder resist layer 262. A side surface of the filling layer 266 may contact the side surface of the second package solder resist layer 262. A lower surface of the filling layer 266 may be positioned at the same or substantially the same level as the lower surface of the second package solder resist layer 262.

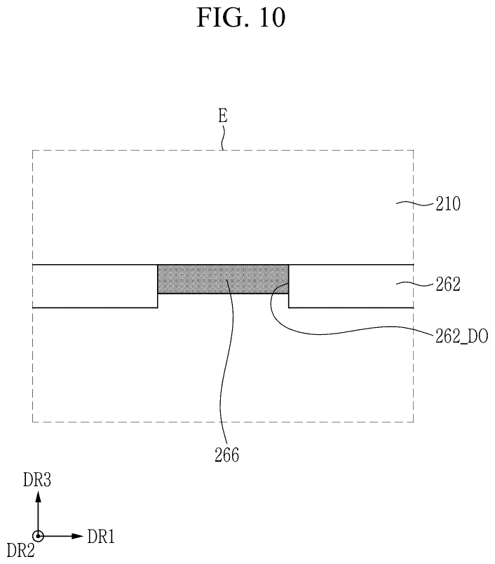

Referring to FIG. 10, the filling layer 266 according to an embodiment may be positioned to fill a portion of the depth of the dummy opening 262_DO.

For example, the upper surface of the filling layer 266 may be positioned to contact the lower surface of the package substrate 210. The upper surface of the filling layer 266 may be positioned at the same or substantially the same level as the upper surface of the second package solder resist layer 262. A lower surface of the filling layer 266 may be positioned at a different level from the lower surface of the second package solder resist layer 262. For example, the lower surface of the filling layer 266 may be positioned higher than the lower surface of the second package solder resist layer 262, but the inventive concept is not limited thereto.

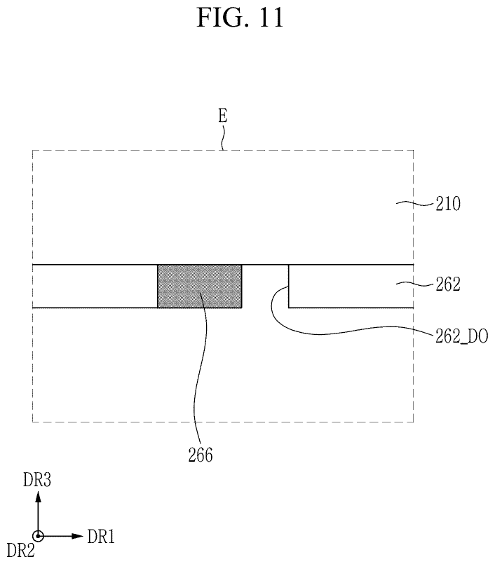

Referring to FIG. 11, the filling layer 266 according to an embodiment may be positioned in a portion of the dummy opening 262_DO.

The upper surface of the filling layer 266 may be positioned to contact the lower surface of the package substrate 210. The upper surface of the filling layer 266 may be positioned at the same or substantially the same level as the upper surface of the second package solder resist layer 262. A first side surface of the filling layer 266 may be in contact with the second package solder resist layer 262, and a second side surface of the filling layer 266 may not be in contact with the second package solder resist layer 262, but the inventive concept is not limited thereto. For example, the side surface of the filler layer 266 may not contact the second package solder resist layer 262. Furthermore, the lower surface of the filling layer 266 may be positioned at a different level from the lower surface of the second package solder resist layer 262.

By arranging the dummy opening 262_DO and the filling layer 266 on the second package solder resist layer 262 arranged on the second side of the package substrate 210, a difference in CTE with the module substrate 110 may be reduced, and reliability of the semiconductor package 200 and the semiconductor module 100 may be improved.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While this disclosure has been described in connection with presented embodiments, it is to be understood that the inventive concept is not limited to the disclosed embodiments, but, on the contrary, is intended to cover various modifications and equivalent dispositions included within the spirit and scope of the appended claims.

### Description of Symbols

100: semiconductor module
110: module substrate
122: module solder resist layer
122_O: module solder resist layer opening
124: module pad
200: semiconductor package
210: package substrate
211: insulating layer
212: wiring layer
214: via
220: semiconductor chip
230: encapsulant
240: connecting member
252: first package solder resist layer
254: first package pad
262: second package solder resist layer
262_O: second package solder resist layer opening
262_DO: dummy opening
264: second package pad

What is claimed is:

1. A semiconductor package comprising:
a package substrate;
a semiconductor chip positioned on a first surface of the package substrate;
a pad positioned on a second surface of the package substrate;
a solder resist layer including an opening positioned on the second surface of the package substrate and the pad, the solder resist layer vertically overlapping at least a portion of the pad, the solder resist layer including a dummy opening spaced apart from the opening; and
a filling layer positioned within the dummy opening,
wherein the dummy opening is positioned farther than the opening from a center of the package substrate in a plan view.

2. The semiconductor package of claim 1, wherein
the package substrate includes an insulating layer and a wiring layer positioned within the insulating layer and electrically connected to the pad.

3. The semiconductor package of claim 1, wherein
the dummy opening is positioned apart from the pad.

4. The semiconductor package of claim 1, wherein
a Young's modulus of the filling layer is greater than a Young's modulus of the solder resist layer.

5. The semiconductor package of claim 1, wherein
a thickness of the filling layer is 50 % or more and 100 % or less of a depth of the dummy opening.

6. The semiconductor package of claim 1, wherein
the dummy opening is positioned between a first vertex of the package substrate and the opening.

7. The semiconductor package of claim 1, wherein
the dummy opening is positioned between a first edge of the package substrate and the opening.

8. The semiconductor package of claim 1, wherein
the filling layer includes at least one of tin (Sn), lead (Pb), silver (Ag), copper (Cu), bismuth (Bi), indium (In), antimony (Sb), zinc (Zn), gold (Au), or nickel (Ni).

9. The semiconductor package of claim 1, wherein
the opening and the dummy opening extend through the solder resist layer in a vertical direction.

10. The semiconductor package of claim 1, wherein
a depth of the dummy opening is 10 μm or more and 20 μm or less.

11. A semiconductor package comprising:
a package substrate;
a semiconductor chip positioned on a first surface of the package substrate;
a plurality of pads positioned on a second surface of the package substrate;
a solder resist layer including a plurality of openings positioned on the package substrate and the pads, the plurality of openings exposing the plurality of pads respectively, the solder resist layer including a dummy opening positioned apart from the openings; and
a filling layer positioned within the dummy opening.

12. The semiconductor package of claim 11, wherein
the openings are positioned in a grid shape in a plan view.

13. The semiconductor package of claim 12, wherein
the dummy opening is positioned at outside a corner of an opening area, which is an area in which the openings are positioned in a plan view.

14. The semiconductor package of claim 11, wherein
the dummy opening is positioned apart from the pads.

15. The semiconductor package of claim 11, wherein
the filling layer includes at least one of tin (Sn), lead (Pb), silver (Ag), copper (Cu), bismuth (Bi), indium (In), antimony (Sb), zinc (Zn), gold (Au), or nickel (Ni).

16. The semiconductor package of claim 11, wherein
the solder resist layer includes a plurality of dummy openings.

17. The semiconductor package of claim 11, wherein
a thickness of the filling layer is 50 % or more and 100 % or less of a depth of the dummy opening.

18. The semiconductor package of claim 11, wherein
the dummy opening has any one of a circular, elliptical, polygonal, L-shaped, C-shaped, and annular shape.

19. A semiconductor module comprising:
a package substrate;
a semiconductor chip positioned on a first surface of the package substrate;
a pad positioned on a second surface of the package substrate;
a solder resist layer including an opening positioned on the package substrate and the pad, the opening vertically overlapping at least a portion of the pad, the solder resist layer including a dummy opening spaced apart from the opening;
a filling layer positioned within the dummy opening; and
a solder ball positioned within the opening.

20. The semiconductor module of claim 19, wherein
the filling layer includes at least one of tin (Sn), lead (Pb), silver (Ag), copper (Cu), bismuth (Bi), indium (In), antimony (Sb), zinc (Zn), gold (Au), or nickel (Ni).
